(19) United States
(12) Patent Application Publication
(10) Pub. No.: US 2026/0186601 A1
(43) Pub. Date: Jul. 2, 2026

(54) PIXEL CIRCUIT, AND DISPLAY PANEL AND DISPLAY DEVICE INCLUDING THE PIXEL CIRCUIT

(71) Applicant: LG Display Co., Ltd., Seoul (KR)

(72) Inventors: Mi Ji LEE, Paju-si (KR); Jeong Hwan KIM, Paju-si (KR)

(73) Assignee: LG Display Co., Ltd., Seoul (KR)

(21) Appl. No.: 19/379,338

(22) Filed: Nov. 4, 2025

(30) Foreign Application Priority Data
Dec. 26, 2024 (KR) 10-2024-0196686

(51) Int. Cl. G06F 3/041; G06F 3/044; G09G 3/3233

(52) U.S. Cl. CPC G06F 3/0418; G06F 3/0412; G09G 3/3233; G06F 3/0446; G09G 2300/0819; G09G 2300/0852; G09G 2310/08; G09G 2330/021; G09G 2354/00

(57) ABSTRACT

A pixel circuit, and a display panel and display device including the pixel circuit are disclosed. The pixel circuit includes a light-emitting element; a compensation circuit configured to supply current to the light-emitting element; and a diode and a switch transistor connected in series between an anode electrode of the light-emitting element and a constant voltage node to which an anode reset voltage is applied. When the diode and the switch transistor are turned on, the voltage of the anode electrode is reset to the anode reset voltage.

### CROSS-REFERENCE TO RELATED APPLICATION

This application claims priority to and the benefit of Korean Patent Application No. 10-2024-0196686, filed Dec. 26, 2024, the disclosure of which is incorporated herein by reference in its entirety.

### BACKGROUND

### Technical Field

The present disclosure relates to a pixel circuit, and a display panel and display device including the pixel circuit.

### Description of Related Art

A touch display device capable of sensing a user's finger or pen input is applied to various electronic devices to improve user convenience. The display panel of a touch display device includes pixels that visually reproduce images and a touch screen for sensing touch input.

In a touch display device, interference between signals applied to pixels and signals applied to touch sensors of the touch screen must be minimized. In the case of a display panel to which a touch screen composed of capacitive type touch sensors is applied, the pixel circuit and the touch sensor circuit are physically arranged close to each other, and electrical interference with the pixel circuit may increase noise in the touch sensor signal.

### BRIEF SUMMARY

The present disclosure provides a pixel circuit, and a display panel and a display device including the pixel circuit, wherein the pixel circuit is electrically coupled to touch sensors that visually reproduce an input image, and is configured to reduce noise increase in the touch sensors due to electrical interference with the pixels.

The features of the present disclosure are not limited to the above-mentioned features, and other features that are not mentioned will be clearly understood by those skilled in the art from the following description.

A pixel circuit according to one or more embodiments of the present disclosure includes: a light-emitting element; a compensation circuit configured to supply current to the light-emitting element; and a diode and a switch transistor connected in series between an anode electrode of the light-emitting element and a constant voltage node to which an anode reset voltage is applied. When the diode and the second switch transistor are turned on, the voltage of the anode electrode is reset to the anode reset voltage.

The diode may include an anode electrode connected to the anode electrode of the light-emitting element and a cathode electrode connected to the switch transistor. The switch transistor may electrically connect the constant voltage node to the cathode electrode of the diode in response to a scan signal.

A cathode electrode of the light-emitting element may be coupled to a touch sensor through a capacitor.

The compensation circuit may include: a driving transistor including a first electrode connected to a first node, a gate electrode connected to a second node, and a second electrode connected to a third node; a first switch transistor connected between a constant voltage node to which a reference voltage is applied and the second node and turned on in response to a second scan signal; a third switch transistor connected between a data line to which a data voltage is applied and the second node and turned on in response to a first scan signal; a fourth switch transistor connected between a constant voltage node to which a pixel driving voltage is applied and the first node and turned on in response to a first emission signal; and a fifth switch transistor connected between the third node and a fourth node and turned on in response to a second emission signal.

The light-emitting element may include an anode electrode connected to the fourth node, and a cathode electrode connected to a constant voltage node to which a pixel ground voltage is applied. The switch transistor connected to the diode may include a second switch transistor connected between the constant voltage node to which the anode reset voltage is applied and a fifth node and turned on in response to a third scan signal. The diode may include a transistor including a gate electrode and a first electrode connected to the fourth node, and a second electrode connected to the fifth node.

The reference voltage may be lower than the pixel driving voltage and higher than the anode reset voltage. The anode reset voltage may be higher than the pixel ground voltage.

The compensation circuit may further include: a first capacitor connected between the second node and the third node; and a second capacitor connected between the constant voltage node to which the pixel driving voltage is applied and the third node.

The pixel circuit may be driven in the order of an initialization period, a sensing period, a data writing period, an anode reset period, and an emission period. The voltage of the first emission signal may be a gate-on voltage during the sensing period and the emission period, and may be a gate-off voltage during the initialization period, the data writing period, and the anode reset period. The voltage of the second emission signal may be the gate-on voltage during the initialization period, the anode reset period, and the emission period, and may be the gate-off voltage during the sensing period and the data writing period. The voltage of the first scan signal may be the gate-on voltage during the data writing period, and may be the gate-off voltage during the initialization period, the sensing period, the anode reset period, and the emission period. The voltage of the second scan signal may be the gate-on voltage during the initialization period and the sensing period, and may be the gate-off voltage during the data writing period, the anode reset period, and the emission period. The voltage of the third scan signal may be the gate-on voltage during the initialization period, the sensing period, the data writing period, and the anode reset period, and may be the gate-off voltage during the emission period. Each of the first to fifth switch transistors may be turned on in response to the gate-on voltage and may be turned off in response to the gate-off voltage.

The compensation circuit may further include: a sixth switch transistor connected between the constant voltage node to which the reference voltage is applied and a sixth node, and turned on in response to the gate-on voltage of a fourth scan signal during the initialization period, the sensing period, and the data writing period; a first capacitor connected between the second node and the third node; and a second capacitor connected between the third node and the sixth node.

A display panel according to one or more embodiments of the present disclosure includes: a display area in which a plurality of data lines, a plurality of gate lines, a plurality of power lines, and a plurality of sub-pixels are arranged, each of the sub-pixels including the pixel circuit; a touch sensor electrically coupled to the light-emitting element; and a gate driving circuit connected to the gate lines.

A display device according to one or more embodiments of the present disclosure includes: a display panel including a display area in which a plurality of data lines, a plurality of gate lines, a plurality of power lines, and a plurality of sub-pixels are arranged, each of the sub-pixels including the pixel circuit; a touch sensor electrically coupled to the light-emitting element; a gate driving circuit connected to the gate lines; and a data driving circuit connected to the data lines.

The present disclosure may not only improve the power consumption of display devices but also enhances touch sensitivity and accuracy by reducing noise in touch sensors that are electrically coupled with light-emitting elements. This may be achieved by increasing the slew time of the anode voltage during anode reset of the light-emitting element using a diode connected to the anode electrode of the light-emitting element, thereby reducing ripple in the cathode voltage.

The present disclosure may prevent noise in the touch sensor caused when the driving timing of the touch sensor and the anode reset timing of the light-emitting element overlap in terms of time during a blank interval.

The effects of the present disclosure are not limited to the above-mentioned effects, and other effects that are not mentioned will be clearly understood by those skilled in the art from the following description and the appended claims.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a block diagram illustrating a display device according to one embodiment of the present disclosure;

FIG. 2 is a cross-sectional view illustrating an example of the cross-sectional structure of the display panel shown in FIG. 1;

FIG. 3 is a plan view illustrating the touch sensor structure of the touch screen layer TS according to an embodiment of the present disclosure;

FIG. 4 is a diagram illustrating an example of gate scanning;

FIGS. 5A and 5B are diagrams illustrating the difference in luminance of the light-emitting element depending on the number of pulses of the emission signal;

FIG. 6 is a diagram illustrating an example of data addressing and anode reset proceeding sequentially along the gate scan direction;

FIG. 7 is a waveform diagram illustrating an example of the gate signal applied to the pixels, the data addressing timing, the anode reset timing, and the timing at which interference between the light-emitting element and the touch sensor is induced;

FIG. 8 is a circuit diagram illustrating a pixel circuit according to an embodiment of the present disclosure;

FIG. 9 is a circuit diagram illustrating an example of a compensation circuit in detail in the pixel circuit shown in FIG. 8;

FIG. 10 is a waveform diagram illustrating the gate signals shown in FIG. 9;

FIGS. 11 and 12 are waveform diagrams illustrating the anode voltage and cathode voltage of the diode D when the second switch transistor and diode are turned on in the pixel circuit shown in FIG. 9;

FIGS. 13 and 14 are waveform diagrams illustrating the voltage at the fourth node when the second switch transistor is turned on, in the structure in which the second switch transistor is directly connected to the fourth node without the diode in the pixel circuit shown in FIG. 9;

FIG. 15 is a waveform diagram illustrating the ripple of the cathode voltage when the second switch transistor and diode are turned on in the pixel circuit shown in FIG. 9;

FIG. 16 is a waveform diagram illustrating the ripple of the cathode voltage when the second switch transistor is turned on in the pixel circuit shown in FIG. 9, where the second switch transistor is directly connected to the fourth node without a diode;

FIGS. 17A to 17E are circuit diagrams illustrating the operation of the pixel circuit shown in FIG. 9, step by step;

FIG. 18 is a circuit diagram illustrating in detail another example of a compensation circuit in the pixel circuit shown in FIG. 8;

FIG. 19 is a waveform diagram illustrating the gate signals shown in FIG. 18; and

FIGS. 20A to 20E are circuit diagrams illustrating the operation of the pixel circuit shown in FIG. 18, step by step.

### DETAILED DESCRIPTION

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the present disclosure. Further, in describing the present disclosure, detailed descriptions of known related technologies can be omitted to avoid unnecessarily obscuring the subject matter of the present disclosure.

The terms such as “comprising,” “including,” “having,” and “containing” used herein are generally intended to allow other components to be added unless the terms are used with the term “only.” Any references to singular can include plural unless expressly stated otherwise.

Components are interpreted to include an ordinary error range even if not expressly stated.

When a positional or interconnected relationship is described between two components as “on top of,” “above,” “below,” “next to,” “connect or couple with,” “crossing,” “intersecting,” or the like, one or more other components can be interposed between them, unless “immediately” or “directly” is used.

When a temporal antecedent relationship is described as “after”, “following”, “next to”, “before”, or the like, it may not be continuous on a time base unless “immediately” or “directly” is used.

The terms “first,” “second,” and the like can be used to distinguish elements from each other, but the functions or structures of the components are not limited by ordinal numbers or component names in front of the components, and may not define order or sequence. Further, the term “can” fully encompasses all the meanings and coverages of the term “may” and vice versa.

The following embodiments can be partially or entirely bonded to or combined with each other and can be linked and operated in technically various ways. The embodiments can be carried out independently of or in association with each other.

The pixel circuit and the gate drive circuit of the display device can include a plurality of transistors. The transistor can be implemented as a thin film transistor (TFT). The transistors can be implemented as an oxide thin film transistor (Oxide TFT) including an oxide semiconductor, a low temperature poly silicon TFT (LTPS TFT) including a low temperature poly silicon, and the like.

A transistor is a three-electrode element including a gate, a source, and a drain. The source is an electrode that supplies carriers to the transistor. In the transistor, carriers start to flow from the source. The drain is an electrode through which carriers exit from the transistor. In a transistor, carriers flow from a source to a drain. In the case of an n-channel transistor, since carriers are electrons, a source voltage is a voltage lower than a drain voltage such that electrons can flow from a source to a drain. The n-channel transistor has a direction of a current flowing from the drain to the source. In the case of a p-channel transistor, since carriers are holes, a source voltage is higher than a drain voltage such that holes can flow from a source to a drain. In the p-channel transistor, since holes flow from the source to the drain, current flows from the source to the drain. It should be noted that a source and a drain of a transistor are not fixed. For example, a source and a drain can be changed according to an applied voltage. Therefore, the disclosure is not limited in terms of a source and a drain of a transistor. In the following description, a source and a drain of a transistor will be referred to as a first electrode and a second electrode.

A gate signal swings between a gate-on voltage and a gate-off voltage. A transistor is turned on in response to a gate-on voltage and is turned off in response to a gate-off voltage. In the case of an n-channel transistor, the gate-on voltage can be a gate high voltage VGH, and the gate-off voltage can be a gate low voltage VGL. In the case of a p-channel transistor, the gate-on voltage can be the gate low voltage VGL, and the gate-off voltage can be the gate high voltage VGH.

Hereinafter, various embodiments of the present disclosure will be described in detail with reference to the accompanying drawings. All the components of each display device and each gate driving circuit according to all embodiments of the present disclosure are operatively coupled and configured.

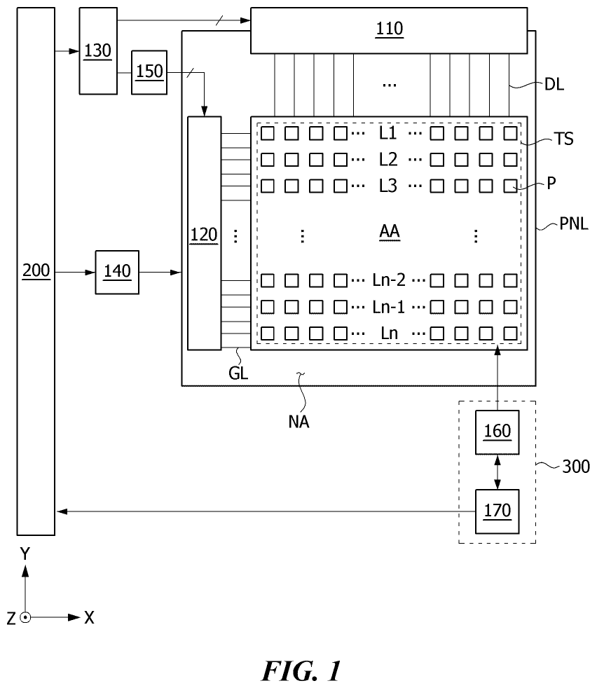

FIG. 1 is a block diagram illustrating a display device according to an embodiment of the present disclosure.

Referring to FIG. 1, the display device may include a display panel driving circuits 110 and 120 for writing image data to pixels P of a display panel PNL and a power circuit 140 for generating power required to drive the pixels and the display panel driving circuits 110 and 120.

The display panel PNL may be a rectangular panel having a width in the X-axis direction (first direction), a length in the Y-axis direction (second direction), and a thickness in the Z-axis direction (third direction), but is not limited thereto. For example, at least a portion of the display panel PNL may have a curved outer portion. The display panel PNL may be implemented with a non-transmissive display panel or a transmissive display panel. The transmissive display panel may be applied to a transparent display device in which an image is displayed on a screen and an actual object in the background is visible. The display panel PNL may also be implemented with a flexible display panel.

The display panel PNL may include a display area AA and a non-display area NA outside the display area AA. The display area AA of the display panel PNL may include a pixel array that displays an image. The pixel array may include a plurality of data lines DL, a plurality of gate lines GL intersecting the plurality of data lines DL, and pixels P arranged in a matrix form.

The pixels P may include two or more sub-pixels for color implementation. For example, each of the pixels P may be divided into a red sub-pixel, a green sub-pixel, and a blue sub-pixel. Each of the pixels P may further include a white sub-pixel. Each of the sub-pixels includes a pixel circuit for driving a light-emitting element. In each of the sub-pixels, the pixel circuit may be connected to a data line DL, a gate line GL, and a power line.

The pixel array of the display area AA may include a plurality of pixel lines L1 to Ln. Each of the pixel lines L1 to Ln may include one line of pixels P arranged along the X-axis direction in the pixel array of the display panel PNL. One horizontal period is a time obtained by dividing one frame period by the total number of pixel lines L1 to Ln. Pixels P arranged in one pixel line parallel to the X-axis may share gate lines GL. Pixels arranged along the column direction parallel to the Y-axis may share a data line DL.

The driving circuits 110 and 120 of the display panel PNL writes pixel data of the input image to the pixels under the control of the timing controller 130.

The timing controller 130 may receive pixel data of an input image from the host system 200 and a timing signal synchronized with the pixel data. The timing signal may include a vertical synchronization signal Vsync, a horizontal synchronization signal Hsync, a main clock CLK, and a data enable signal DE. One cycle of the vertical synchronization signal Vsync may be one frame period. One cycle of the horizontal synchronization signal Hsync and the data enable signal DE may be one horizontal period (1H). The pulse of the data enable signal DE may be synchronized with one line of data to be written to the pixels P of one pixel line. Since the frame period and the horizontal period may be known by counting the data enable signal DE, the vertical synchronization signal Vsync and the horizontal synchronization signal Hsync may be omitted. The timing controller 130 may transmit pixel data of an input image to the data driver 110 and control the operation timing of the data driver 110 and the gate driver 120. The gate timing control signal generated from the timing controller 130 may be input to the gate driver 120 through the level shifter 150.

The level shifter 150 may receive a gate timing control signal and output a start pulse, a shift clock, or the like. The input signal of the level shifter 150 is a signal of a digital signal voltage level, and the output signal of the level shifter 150 may be an analog voltage signal that swings between a gate high voltage VGH and a gate low voltage VGL. The level shifter 150 may convert a low level voltage of a gate timing signal output from a timing controller 130 into a gate low voltage VGL, and may convert a high level voltage into a gate high voltage VGH.

The data driver 110 may receive the pixel data of the input image received as a digital signal from the timing controller 130 to output the data voltage. The data driver 110 may convert the video data of the input image into a gamma compensation voltage using a digital-to-analog converter (hereinafter referred to as “DAC”) and output the data voltage. The gamma reference voltage output from the power circuit 140 may be divided into gamma compensation voltage for each grayscale through the voltage distribution circuit of the data driver 110 and provided to the DAC. The DAC may output the data voltage as a gamma compensation voltage corresponding to the grayscale value of the pixel data. The data voltage output from the DAC may be output to the data line DL through an output buffer in each of the channels of the data driver 110. The data voltage output from the data driver 110 may vary in voltage according to the grayscale value of the pixel data. The data voltage may be determined depending on the pixel data in a dynamic range between the maximum voltage and the minimum voltage that are determined according to the gamma reference voltage.

The circuit of the data driver 110 may be integrated into a drive IC (Integrated Circuit). The drive IC may be directly bonded onto the display panel PNL by a COG (chip on glass) process, or mounted on a flexible film of a COF (chip on film) and electrically connected to data lines DL through the COF bonded to the display panel PNL.

The gate driver 120 may be arranged in the display panel PNL. The gate driver 120 may be arranged in a non-display area NA outside the display area AA in the display panel PNL or at least a portion thereof may be arranged in the display area AA. The gate driver 120 may supply a gate signal to the gate lines GL in a single feeding manner. In the single feeding manner, the gate signal may be applied to one end of the gate line GL. In the double feeding manner, the gate signal may be applied simultaneously to both ends of the gate line GL. The gate signal output from the gate driver 120 may be applied to the pixels P.

A plurality of gate signals may be applied to the pixel circuit of the pixels P. The gate driver 120 may include a plurality of gate drivers that output gate signals of different waveforms. The gate drivers may include circuits such as a shift register and an edge trigger to shift the pulse of the gate signal. The gate signals may include one or more scan signals SC1, SC2, and SC3 and one or more emission signals (hereinafter referred to as “EM signals”) EM1, and EM2 as illustrated in FIG. 7. A plurality of gate lines GL may be connected to the pixel circuit so that gate signals of different waveforms may be applied.

The power circuit 140 may include, but is not limited to, a charge pump, a regulator, a buck converter, and a boost converter. The power circuit 140 may receive a direct current input voltage from the host system 200 and generate power necessary for driving the driving circuits 110 and 120 and pixels P of the display panel PNL. The power circuit 140 may output constant voltages (or DC voltages) such as a gamma reference voltage, a gate high voltage VGH, and a gate low voltage VGL. In addition, the power circuit 140 may output constant voltages provided to the pixels P. The gamma reference voltage may be supplied to the data driver 110. The gate high voltage VGH and the gate low voltage VGL may be supplied to the level shifter 150 and the gate driver 120. Constant voltages input to the pixel circuit, for example, a pixel driving voltage EVDD, a pixel ground voltage EVSS, or the like, may be applied to the pixels P through power lines commonly connected to the pixels P. The pixel ground voltage EVSS may be a cathode voltage. The power circuit 140 may be implemented with a power IC such as a PMIC (Power Management Integrated Circuit) or an ELIC (Electronics Integrated Circuit), but is not limited thereto.

The driving circuits 110 and 120 of the display panel PNL may be driven at a variable refresh rate VRR under the control of the timing controller 130. For example, the timing controller 130 may analyze an input image, and when the input image does not change for a predetermined period of time, may lower the refresh rate to lower the power consumption of the display device. In this case, the driving circuits of the display panel PNL, under the control of the timing controller 130, may lower the refresh rate of the pixels P when a still image is input for a certain period of time to extend the data write cycle of the pixels P and thus to reduce the power consumption of the display device. The display device may operate in standby mode or respond to a user command, causing the driving circuit of the display panel PNL to lower the refresh rate. In addition, the refresh rate may be lowered in the AOD (Always On Display) screen. The AOD screen is a portion of the pixel area of the display area AA on which brief information, such as battery remaining amount and time, preset in the standby mode is displayed.

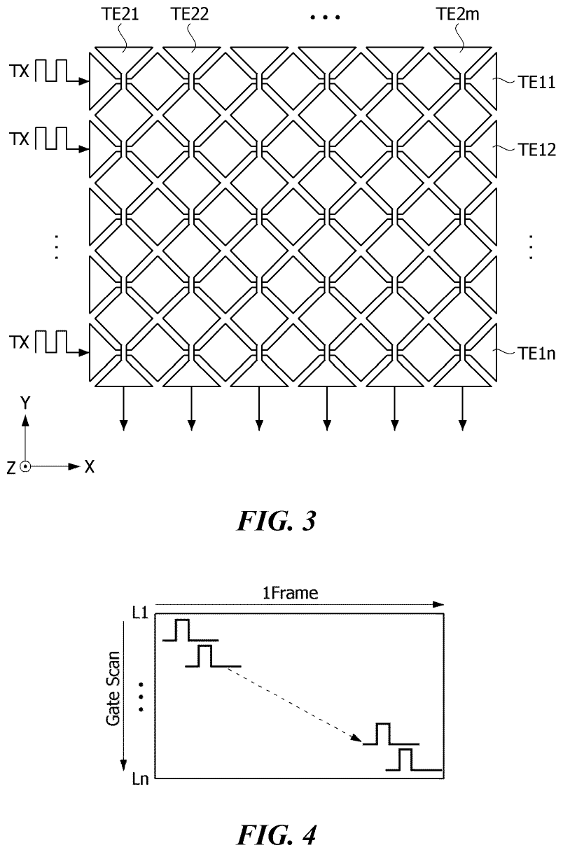

The display panel PNL includes at least a touch screen layer TS overlapping the display area AA. The touch sensors arranged on the touch screen layer TS may be implemented with capacitance type touch sensors. Here, the capacitance may be self-capacitance or mutual capacitance. The structure of the touch screen illustrated in FIG. 3 is a touch sensor of the mutual capacitance type, but the present disclosure is not limited thereto.

The display device further includes a sensor driving circuit 300. The sensor driving circuit 300 may sense a touch input by applying driving signals to the touch sensors and measuring the change amount of charge or voltage before and after the touch input (or touch event) in each touch sensor. The sensor driving circuit 300 may include a sensor driver 160 and a sensor controller 170. The sensor driver 160 may be implemented with a ROIC (Read-out IC), and the sensor controller 170 may be implemented with an MCU (Micro Controller Unit, MCU), but are not limited thereto.

The sensor driver 160 may supply driving signals to the touch sensors, and may convert the change amount of charge or voltage before and after the touch input into digital data and then output raw data. The sensor driver 160 may include a first driver that supplies driving signals to the touch sensors, and a second driver that includes an amplifier and an ADC (Analog to digital converter). The sensor driver 160 may further include a switch circuit that selectively connects the sensor lines, to which the touch sensors are connected, to the first driver and the second driver. The switch circuit may be implemented with a multiplexer, but is not limited thereto.

The sensor controller 170 may perform a touch sensing algorithm to analyze the raw data, which is input as digital signals from the sensor driver 160 during the touch sensing interval, and to calculate the coordinates of the touch input location. The sensor controller 170 may compare the raw data with a preset threshold value to identify whether a touch input has occurred.

The sensor signal TD output from the sensor controller 170 may include an identification information of each touch input and a coordinate information of the touch input location and may be transmitted to the host system 200.

The host system 200 may scale an image signal from a video source to match the resolution of the display panel PNL, and may transmit it to the timing controller 130 together with the timing control signal. The host system 200 may execute an application program or user command associated with the coordinate values of the touch input in response to the sensor signal TD received as a digital signal.

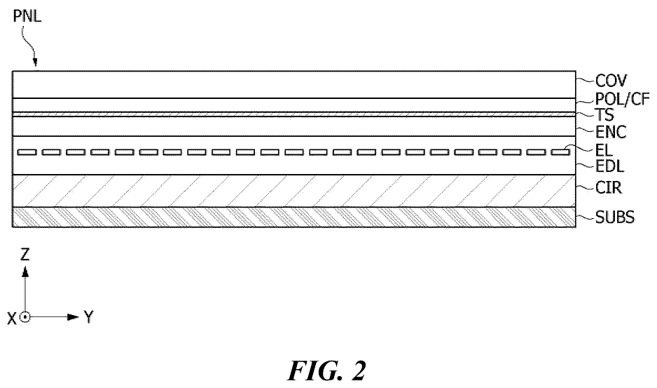

FIG. 2 is a cross-sectional view illustrating an example of the cross-sectional structure of the display panel shown in FIG. 1.

Referring to FIG. 2, the display panel PNL may include a circuit layer CIR, a light-emitting element layer EDL, an encapsulation layer ENC, a touch screen layer TS, and a cover glass COV arranged on a substrate SUBS, but is not limited thereto.

The circuit layer CIR may include pixel circuits connected to wires such as data lines DL, gate lines GL and power lines, and circuits of a gate driver 120. The wires and circuit elements of the circuit layer CIR may include a plurality of insulating layers, two or more metal layers separated by the insulating layer, and an active layer (or semiconductor layer) including a semiconductor material of a TFT.

The light-emitting element layer EDL may include a plurality of light-emitting elements EL driven by pixel circuits. The light-emitting elements EL may be but are not limited to inorganic light-emitting elements, and may be for example organic light emitting diodes OLED or micro LED, but are not limited thereto. The OLED may be implemented with a tandem structure in which a plurality of emission layers are stacked. The OLED having the tandem structure may improve the luminance and lifetime of a pixel.

The encapsulation layer ENC may cover the light-emitting element layer EDL to seal the circuit layer CIR and the light-emitting element layer EDL. The encapsulation layer ENC may have a structure in which organic films and inorganic films are alternately stacked. The inorganic film may block the penetration of moisture or oxygen. The organic film may planarize the surface of the inorganic film. If the organic films and inorganic films are stacked in multiple layers, the migration path of moisture or oxygen due to the penetration of moisture or oxygen from the outside becomes longer compared to a single layer, so that the penetration of moisture or oxygen affecting the light-emitting element layer EDL may be effectively blocked.

The touch screen layer TS may be arranged on the encapsulation layer ENC. The touch screen layer TS may include touch sensors and wires connected to the touch sensors. The touch screen layer TS may include sensor lines and an insulating film. The sensor lines may be metal wires or wires formed of a transparent electrode material such as ITO (Indium tin oxide). The sensor lines may be patterned in a mesh shape to increase the transmittance of the pixels. The insulating film of the touch screen layer TS may insulate the sensor lines and may planarize the surface of the touch screen layer TS.

A polarizing plate POL or a color filter layer CF may be arranged on the touch screen layer TS. The polarizing plate POL may convert the polarization of external light reflected by the metal of the touch sensor layer TS and the circuit layer CIR to improve the visibility and contrast ratio of the image reproduced on the display panel PNL. The color filter layer CF may absorb some of the wavelengths of light reflected from the metal in the circuit layer CIR and touch screen layer TS, thereby replacing the role of the polarizing plate POL and improving the visibility of the image reproduced on the display panel PNL and the color purity of the image. A cover glass COV may be adhered on the polarizing plate POL or the color filter layer CF. The color filter layer CF may include red, green, and blue color filters. The color filter layer CF may further include a black matrix.

FIG. 3 is a plan view illustrating the touch sensor structure of the touch screen layer TS according to an embodiment of the present disclosure.

Referring to FIG. 3, the touch screen layer TS includes a plurality of first sensor lines TE11 to TE1n and a plurality of second sensor lines TE21 to TE2m that intersect with the first sensor lines TE11 to TE1n.

The first sensor lines TE11 to TE1n and the second sensor lines TE21 to TE2m may be arranged so that they are insulated from each other in the same plane on the insulating layer. At the intersection of the first sensor lines TE11 to TE1n and the second sensor lines TE21 to TE2m, the first sensor lines TE11 to TE1n or the second sensor lines TE21 to TE2m may be connected through a bridge penetrating the insulating layer.

Mutual capacitance of the touch sensor may be formed at intersections between the first sensor lines TE11 to TE1n and the second sensor lines TE21 to TE2m. The first sensor lines TE11 to TE1n may include TX electrodes of the touch sensor to which a pulse of a driving signal TX is applied. The second sensor lines TE21 to TE2 may include RX sensor electrodes that sense a charge charged in the touch sensor. The change amount of the charge or voltage charged in the touch sensor may be sensed. The amount of charge charged in the touch sensor changes before and after a touch input, and when the change amount is greater than a threshold value, it is recognized as a touch input.

When pixels and touch sensors of the display panel are driven, interference between the pixels and the touch sensor may cause variations in the charge or voltage of the touch sensor, thereby increasing noise in the signal read from the touch sensor. For example, when a light-emitting element of pixels is driven at high speed, the driving timing of the touch sensor and the anode reset timing of the light-emitting element may overlap in terms of time. In this case, when the anode voltage of the light-emitting element is reset, the variation in the anode voltage may cause voltage variations at the cathode electrode of the light-emitting element, which is capacitance-coupled to the anode electrode through the capacitance of the light-emitting element, and at an electrode of the touch sensor, for example, a RX electrode. An example in which the anode reset timing of the light-emitting element and the driving timing of the touch sensor overlap will be described in detail with reference to FIGS. 4 to 7.

The gate driver 120 applies, under the control of the timing controller 130, a pulse of a gate signal to a gate line connected to the first pixel line L1, and then shifts it to the subsequent pixel lines, applying a pulse of the gate signal to the gate lines. Therefore, the pulse of the gate signal may be shifted along the gate scan direction starting from the first pixel line L1 toward the n-th pixel line Ln as shown in FIG. 4. The data addressing in which a data voltage is applied to a pixel circuit, the anode reset of a light-emitting element, and the emission of the light-emitting element may be sequentially performed on a per-pixel line basis along the gate scan direction. The gate signal for data addressing, the gate signal for anode reset, and the gate signal for the emission of the light-emitting element may be separated so that the data addressing, the anode reset of the light-emitting element, and the emission of the light-emitting element may be individually controlled.

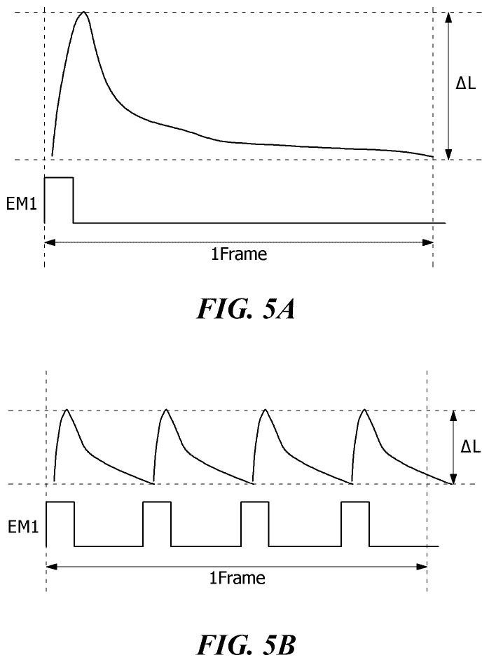

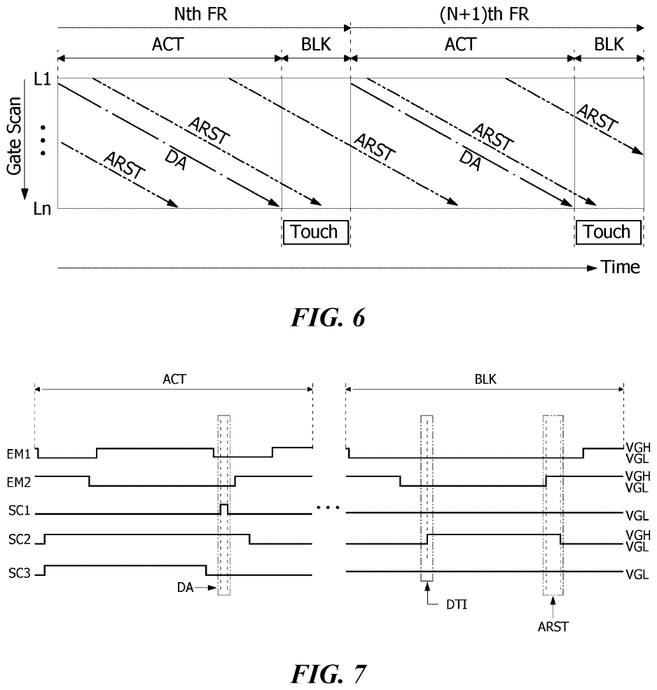

As illustrated in FIG. 5A, if a pulse of an EM signal EM1 controlling the emission period and frequency of the light-emitting element is generated once per one frame period, the luminance difference ΔL of the light-emitting element within one frame period may increase. In order to reduce this luminance difference ΔL, the pulse of the EM signal EM1 may be repeatedly generated multiple times within one frame period, as shown in FIG. 5B. The anode voltage of the light-emitting element may be reset before the emission of the light-emitting element. Accordingly, when the pulse of the EM signal EM1 is repeated multiple times within one frame period, the anode reset of the light-emitting element may also be repeated multiple times within one frame period, as shown in FIG. 6.

FIG. 6 is a diagram illustrating an example of data addressing and anode reset proceeding sequentially along the gate scan direction. In FIG. 6, the horizontal axis represents time, and the vertical axis represents the length in the Y-direction in the display panel. In FIG. 6, ‘Nth FR’ represents the Nth (N is a natural number) frame period, and ‘(N+1)th FR’ represents the (N+1)th frame period. ‘L1 . . . . Ln’ represent the first to nth pixel lines. FIG. 7 is a waveform diagram illustrating an example of the gate signal applied to the pixels, the data addressing timing, the anode reset timing, and the timing at which interference between the light-emitting element and the touch sensor is induced. In FIGS. 6 and 7, ‘DA’ represents data addressing, and ‘ARST’ represents an anode reset of a light-emitting element.

Referring to FIGS. 6 and 7, each of the Nth and (N+1)th frame periods Nth FR and (N+1)th FR may be divided into an active period ACT and a blank period BLK.

To reduce interference between pixels and touch sensors, data addressing DA is performed during the active period ACT to write pixel data to all pixels, and the touch sensors are driven during the blank period BLK.

Data addressing DA is sequentially performed from the first pixel line L1 to the nth pixel line Ln along the gate scan direction during the active period ACT to write pixel data to the pixels. During the blank period BLK, driving signals are applied to the TX electrodes of the touch sensors, and a change in the amount of charge charged in the touch sensor may be sensed through the RX electrodes. However, when the anode reset ARST of the light-emitting element, which is performed before the emission of the light-emitting element, is also performed during the blank period BLK, the light-emitting element and the touch sensor may interfere with each other through capacitance-coupling. For example, in FIG. 7, at the rising edge of the pulse where the voltage of the third scan signal rises from the gate low voltage VGL to the gate high voltage VGH, interference DTI between the light-emitting element and the touch sensor may occur, thereby generating noise in the signal of the touch sensor. During the anode reset ARST, the source voltage of the driving transistor for driving the light-emitting element may be reset simultaneously.

In order to reduce interference between the light-emitting element and the touch sensor that occurs when the anode of the light-emitting element is reset, a separate shielding film may be added between the encapsulation layer ENC and the touch screen layer TS in FIG. 2; however, in this case, the manufacturing cost of the display panel increases. An embodiment of the present disclosure improves the structure of the pixel circuit to reduce noise that affects the touch sensor signal when the anode of the light-emitting element is reset without adding a shielding film to the display panel.

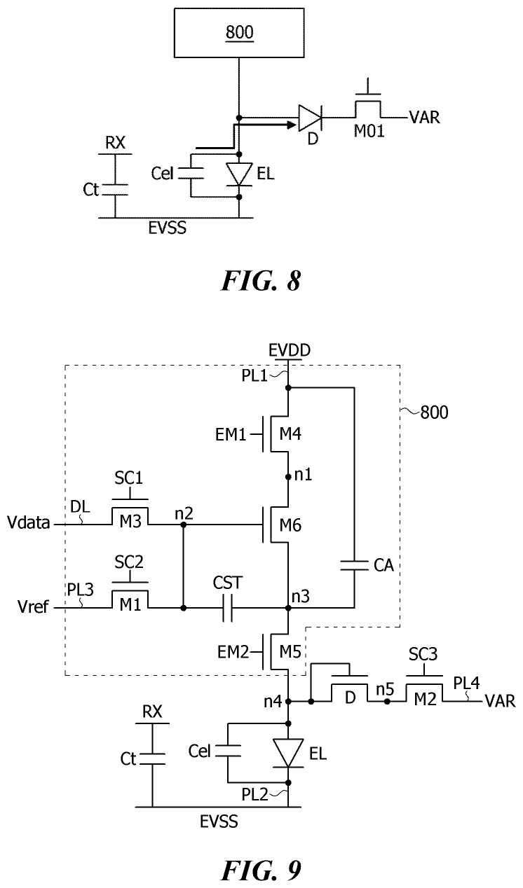

FIG. 8 is a circuit diagram illustrating a pixel circuit according to an embodiment of the present disclosure.

Referring to FIG. 8, the pixel circuit includes a compensation circuit 800 for driving a light-emitting element EL, a diode D connected in series to the anode electrode of the light-emitting element EL, and a switch transistor M01.

The compensation circuit 800 includes a driving transistor for supplying current to the light-emitting element EL, a capacitor for sampling a threshold voltage of the driving transistor and maintaining a gate-source voltage of the driving transistor, and a plurality of switch transistors. The switch transistors of the compensation circuit 800 switch a signal path of the compensation circuit during initialization of a pixel circuit, sensing a threshold voltage of the driving transistor, writing data, and emission of the light-emitting element.

The light-emitting element EL includes an anode electrode, a cathode electrode, and an emission layer formed between these electrodes. The light-emitting element EL includes a capacitor Cel formed between the anode electrode and the cathode electrode. The anode electrode of the light-emitting element EL is connected to a compensation circuit 800 and also connected to the anode electrode of a diode D. The cathode electrode of the light-emitting element EL is connected to an EVSS node to which a pixel ground voltage EVSS is applied. A diode D and a switch transistor M01 are connected in series between the anode electrode of the light-emitting element EL and the VAR node to which an anode reset voltage VAR is applied. The diode D includes an anode electrode connected to the anode electrode of the light-emitting element EL and a cathode electrode to which the anode reset voltage VAR is applied. The diode D may be implemented with a transistor having substantially the same structure as the switch transistors of the pixel circuit as shown in FIG. 9.

The switch transistor M01 is turned on in response to the gate-on voltage. When the diode D is turned on after the switch transistor M01 is turned on, the anode voltage of the light-emitting element EL is discharged to the anode reset voltage VAR, so that the anode voltage of the light-emitting element EL may be reset.

In FIG. 8, ‘Ct’ is a capacitor formed between the cathode electrode of the light-emitting element EL and the RX electrode of the touch sensor. The capacitor Ct may be formed of the RX electrode of the touch sensor, the cathode electrode of the light-emitting element EL, and an insulating layer or dielectric layer of the encapsulation layer ENC arranged between these electrodes. The capacitor Ct may be a parasitic capacitance.

The diode D may be turned on when its anode voltage becomes higher than its cathode voltage by its threshold voltage after the switch transistor M01 is turned on. After both the diode D and the switch transistor M01 are turned on, the anode electrode of the light-emitting element EL may be discharged to the anode reset voltage VAR, so that the anode voltage of the light-emitting element EL may be reset.

The diode D increases the slew time of the anode voltage when the anode voltage of the light-emitting element EL is reset, thereby reducing the slew rate. Due to the diode D, the ripple of the voltage (cathode voltage) of the cathode electrode of the light-emitting element coupled to the anode electrode of the light-emitting element through the capacitor Cel may be reduced. If the ripple in the cathode voltage of the light-emitting element is reduced, the ripple applied to the RX electrode of the touch sensor coupled to the cathode electrode of the light-emitting element EL through the capacitor Ct is reduced, so that noise in the touch sensor signal may be reduced.

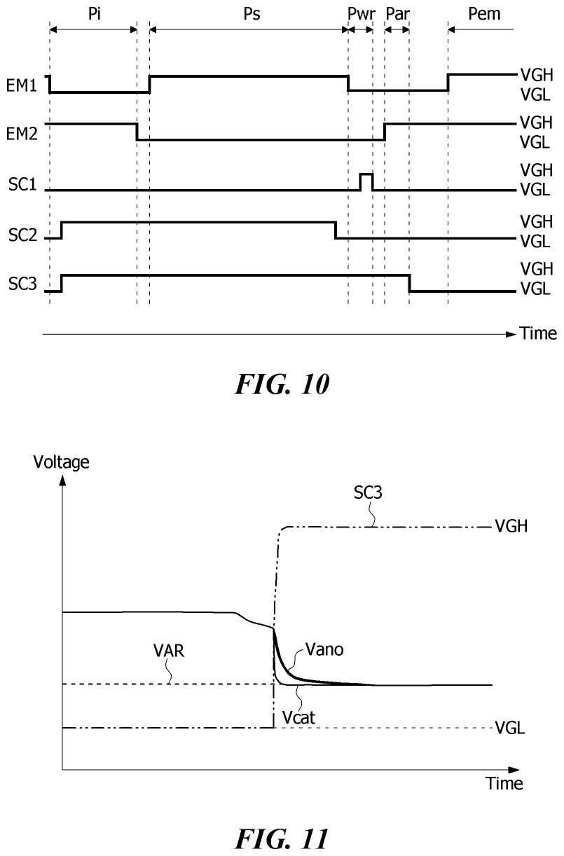

FIG. 9 is a circuit diagram illustrating an example of a compensation circuit in detail in the pixel circuit shown in FIG. 8. FIG. 10 is a waveform diagram illustrating the gate signals shown in FIG. 9. In FIG. 9, any description that is redundant to the description of FIG. 8 described above may be omitted.

Referring to FIGS. 9 and 10, a compensation circuit 800 of a pixel circuit includes a driving transistor M6, a plurality of switch transistors M1, M3, M4, and M5, a first capacitor CST, and a second capacitor CA. The transistors M1 to M6 and the diode D of the pixel circuit may be implemented with an n-channel Oxide TFT, but are not limited thereto.

The pixel circuit is connected to a data line DL to which a data voltage Vdata of pixel data is applied, and to gate lines to which gate signals SC1, SC2, SC3, EM1, and EM2 are applied. The pixel circuit is connected to a first constant voltage node PL1 to which a pixel driving voltage EVDD is applied, a second constant voltage node PL2 to which a pixel ground voltage EVSS is applied, a third constant voltage node PL3 to which a reference voltage Vref is applied, and a fourth constant voltage node PL4 to which an anode reset voltage VAR is applied. These constant voltage nodes are connected to corresponding power lines.

The voltage level of each of the constant voltages EVDD, EVSS, Vref, and VAR applied to the pixel circuit may be set in consideration of the voltage margin for saturation region operation. The voltage level of the constant voltages EVDD, EVSS, Vref, and VAR may be set under the condition of EVDD>Vref>VAR>EVSS. For example, the pixel driving voltage EVDD may be a voltage between 7 [V] and 10 [V], the reference voltage Vref may be a voltage between 1 [V] and 2 [V], the anode reset voltage VAR may be a voltage between −2 [V] and −4 [V], and the pixel ground voltage EVSS may be a voltage between −5 [V] and −7 [V], but are not limited thereto. The data voltage Vdata output from the data driver 110 has a dynamic range set between the reference voltage Vref and the pixel driving voltage EVDD. For example, the minimum voltage of the data voltage Vdata may be set to a voltage close to the reference voltage Vref, and the maximum voltage of the data voltage Vdata may be set to a voltage close to the pixel driving voltage EVDD. The data voltage Vdata may be selected according to pixel data within a dynamic range of 3 [V] to 5 [V], but is not limited thereto.

The gate high voltage VGH may be set to a voltage higher than the pixel driving voltage EVDD, and the gate low voltage VGL may be set to a voltage lower than the pixel ground voltage EVSS. For example, the gate high voltage VGH may be a voltage between 11 [V] and 12 [V], and the gate low voltage VGL may be between −8 [V] and −10 [V], but are not limited thereto. Hereinafter, the gate high voltage VGH is referred to as the gate-on voltage, and the gate low voltage VGL is referred to as the gate-off voltage.

The gate signals SC1, SC2, SC3, EM1, and EM2 include a pulse which swings between the gate-on voltage VGH and the gate-off voltage VGL.

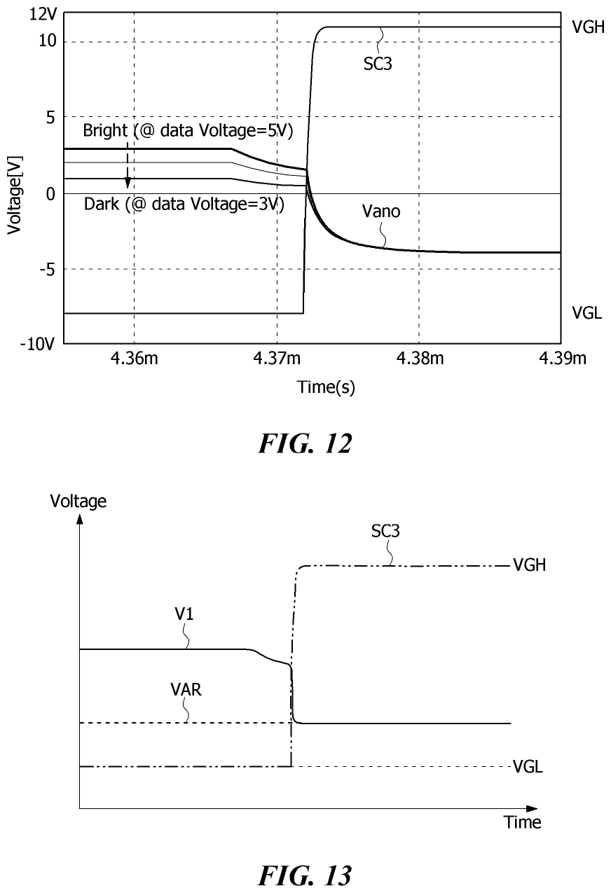

During one frame period, the illustrated pixel circuit may be driven in the order of an initialization period Pi, a sensing period Ps, a data writing period Pwr, an anode reset period Par, and an emission period Pem, as shown in FIG. 12. The initialization period Pi, the sensing period Ps, the data writing period Pwr, the anode reset period Par, and the emission period Pem may be defined by the waveforms of the gate signals SC1, SC2, SC3, EM1, and EM2.

The voltage of the first EM signal EM1 is the gate-on voltage VGH during the sensing period Ps and the emission period Pem, and is the gate-off voltage VGL during the initialization period Pi, the data writing period Pwr, and the anode reset period Par. The fourth switch transistor M4 is turned on in response to the gate-on voltage VGH of the first EM signal EM1, and is turned off in response to the gate-off voltage VGL of the first EM signal EM1.

The voltage of the second EM signal EM2 is the gate-on voltage VGH during the initialization period Pi, the anode reset period Par, and the emission period Pem, and is the gate-off voltage VGL during the sensing period Ps and the data writing period Pwr. The fifth switch transistor M5 is turned on in response to the gate-on voltage VGH of the second EM signal EM2, and is turned off in response to the gate-off voltage VGL of the second EM signal EM2.

The voltage of the first scan signal SC1 is generated as a pulse of gate-on voltage VGH synchronized with the data voltage Vdata of pixel data during the data writing period Pwr, and is a gate-off voltage VGL during other periods Pi, Ps, Par, and Pem. The third switch transistor M3 is turned on in response to the gate-on voltage VGH of the first scan signal SC1, and is turned off in response to the gate-off voltage VGL of the first scan signal SC1.

The voltage of the second scan signal SC2 is generated as a pulse of gate-on voltage VGH during the initialization period Pi and the sensing period Ps, and is a gate-off voltage VGL during other periods Pwr, Par, and Pem. The first switch transistor M1 is turned on in response to the gate-on voltage VGH of the second scan signal SC2, and is turned off in response to the gate-off voltage VGL of the second scan signal SC2.

The voltage of the third scan signal SC3 is the gate-on voltage VGH during the initialization period Pi, the sensing period Ps, the data writing period Pwr, and the anode reset period Par, and is the gate-off voltage VGL during the emission period Pem. The second switch transistor M2 is turned on in response to the gate-on voltage VGH of the third scan signal SC3, and is turned off in response to the gate-off voltage VGL of the third scan signal SC3.

The driving transistor M6 generates current according to the gate-source voltage Vgs to drive the light-emitting element EL. The gate-source voltage Vgs of the driving transistor M6 is a voltage applied between the second node n2 and the third node n3. The driving transistor M6 includes a first electrode connected to the first node n1, a gate electrode connected to the second node n2, and a second electrode connected to the third node n3.

The anode electrode of the light-emitting element EL may be connected to a fourth node n4, and the cathode electrode may be connected to a second constant voltage node PL2 to which a pixel ground voltage EVSS is applied. The light-emitting element EL includes a capacitor Cel formed between the anode electrode and the cathode electrode.

The first capacitor CST is connected between the second node n2 and the third node n3. The first capacitor CST is initialized during the initialization period Pi, and then stores the threshold voltage of the driving transistor M6 during the sensing period Ps. The first capacitor CST stores the data voltage Vdata of pixel data compensated by the threshold voltage of the driving transistor M6 during the data writing period Pwr, and then maintains the gate-source voltage Vgs of the driving transistor M6 during the anode reset period Par and the emission period Pem.

The second capacitor CA may be connected between the first constant voltage node PL1 and the third node n3. The pixel driving voltage EVDD is applied to the first constant voltage node PL1. The second capacitor CA prevents loss of the data voltage Vdata. The transfer rate (Data DR) of the data voltage Vdata is as shown in Equation 1 below:

$$Data DR = 1 - \frac{CST}{CST + {C}_{{DTS}_{- hold}}} , {C}_{{DTS}_{- hold}} = CA + {C}_{{DTS}_{- par}} \qquad Equation 1$$

Here, CST is a capacitance of the first capacitor CST, CA is a capacitance of the second capacitor CA, CDTS_par is the parasitic capacitance connected to the third node n3. The larger the CDTS_hold value, the more the data voltage Vdata is transmitted completely, resulting in less loss of the data voltage Vdata.

A first switch transistor M1 is connected between a third constant voltage node PL3 to which a reference voltage Vref is applied and a second node n2 and is turned on in response to a gate-on voltage VGH of a second scan signal SC2. When the first switch transistor M1 is turned on, the reference voltage Vref is applied to the second node n2. The first switch transistor M1 is in the off-state when the voltage of the second scan signal SC2 is a gate-off voltage VGL. The first switch transistor M1 includes a first electrode connected to the third constant voltage node PL3, a gate electrode connected to a gate line to which the second scan signal SC2 is applied, and a second electrode connected to the second node n2.

The second switch transistor M2 is connected between a fourth constant voltage node PL4 to which an anode reset voltage VAR is applied and a fifth node n5 and is turned on in response to a gate-on voltage VGH of a third scan signal SC3. When the second switch transistor M2 is turned on, the anode reset voltage VAR is applied to the fifth node n5. The second switch transistor M2 is in the off-state when the voltage of the third scan signal SC3 is a gate-off voltage VGL. The second switch transistor M2 includes a first electrode connected to the fourth constant voltage node PL4, a gate electrode connected to a gate line to which the third scan signal SC3 is applied, and a second electrode connected to the fifth node n5.

A third switch transistor M3 is connected between a data line DL to which a data voltage Vdata of pixel data is applied and a second node n2 and is turned on in response to a gate-on voltage VGH of a first scan signal SC1. When the third switch transistor M3 is turned on, the data voltage Vdata is applied to the second node n2. The third switch transistor M3 is in the off-state when the voltage of the first scan signal SC1 is a gate-off voltage VGL. The third switch transistor M3 includes a first electrode connected to the data line DL, a gate electrode connected to a gate line to which the first scan signal SC1 is applied, and a second electrode connected to a second node n2.

The fourth switch transistor M4 is connected between a first constant voltage node PL1 to which a pixel driving voltage EVDD is applied and a first node n1 and is turned on in response to a gate-on voltage VGH of the first EM signal EM1. When the fourth switch transistor M4 is turned on, the pixel driving voltage EVDD is applied to the first node n1. The fourth switch transistor M4 includes a first electrode connected to the first constant voltage node PL1, a gate electrode connected to a gate line to which the first EM signal EM1 is applied, and a second electrode connected to the first node n1.

The fifth switch transistor M5 is connected between the third node n3 and the fourth node n4 and is turned on in response to the gate-on voltage VGH of the second EM signal EM2. When the fifth switch transistor M5 is turned on, the third node n3 is electrically connected to the fourth node n4. The fifth switch transistor M5 includes a first electrode connected to the third node n3, a gate electrode connected to a gate line to which the second EM signal EM2 is applied, and a second electrode connected to the fourth node n4.

The diode D is connected between the fourth node n4 and the fifth node n5 and is turned on when the voltage of the fourth node n4 is higher than the voltage of the fifth node n5 by a threshold voltage of the diode D. When the diode D is turned on, the fourth node n4 is electrically connected to the fifth node n5. When both the second switch transistor M2 and the diode D are turned on, the anode voltage of the light-emitting element EL may be reset. When the diode D is implemented with a transistor, the diode D includes a gate electrode and a first electrode (anode electrode) connected to the fourth node n4, and a second electrode (cathode electrode) connected to the fifth node n5.

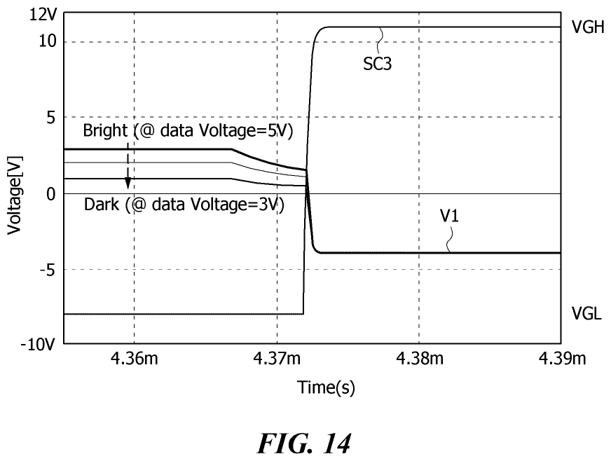

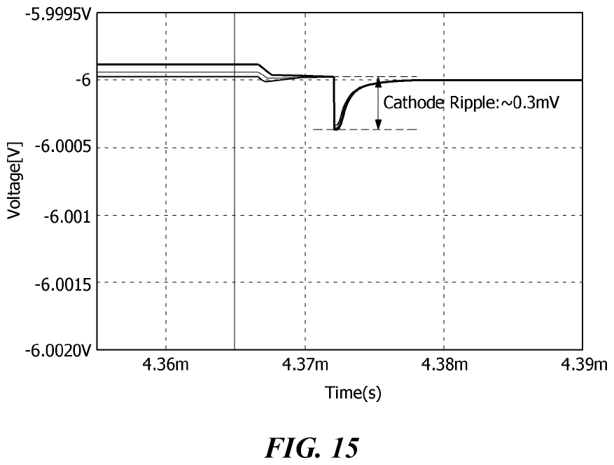

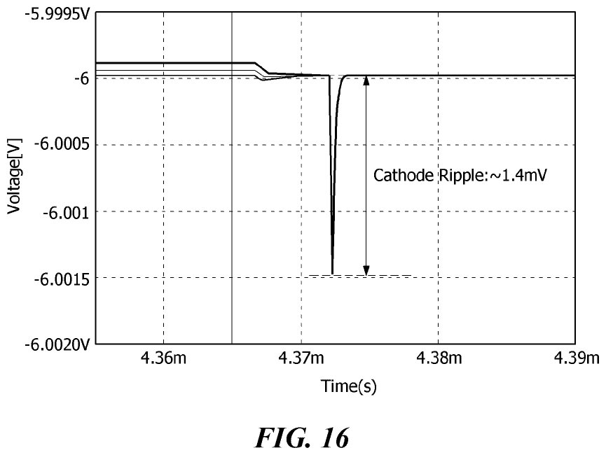

FIGS. 11 and 12 are waveform diagrams illustrating the anode voltage and cathode voltage of the diode D when the second switch transistor M2 and diode D are turned on in the pixel circuit shown in FIG. 9. In FIGS. 11 and 12, ‘Vano’ is the anode voltage of the diode D, that is, the voltage of the fourth node n4. ‘Vcat’ is the cathode voltage of the diode D, that is, the voltage of the fifth node n5. In FIG. 12, “Bright@data voltage=5V)” is a high-grayscale data voltage at which the light-emitting element emits light with high luminance. “Dark@data voltage=3V)” is a low-grayscale data voltage at which the luminance of the light-emitting element decreases. FIGS. 13 and 14 are waveform diagrams illustrating the voltage V1 of the fourth node n4 when the second switch transistor M2 is turned on, in the structure in which the second switch transistor M2 is directly connected to the fourth node n4 without the diode D in the pixel circuit shown in FIG. 9. FIG. 15 is a waveform diagram illustrating the ripple of the cathode voltage when the second switch transistor M2 and the diode D are turned on in the pixel circuit shown in FIG. 9. FIG. 16 is a waveform diagram illustrating the ripple of the cathode voltage when the second switch transistor M2 is turned on, in the structure in which the second switch transistor M2 is directly connected to the fourth node n4 without the diode D in the pixel circuit shown in FIG. 9.

As may be seen from the comparison of FIGS. 11 and 13, when the second transistor M2 is turned on due to the diode D and the anode voltage of the light-emitting element EL is reset, the slew time of the anode voltage Vano of the light-emitting element EL and the diode D becomes longer, so that the ripple applied to the cathode electrode of the light-emitting element EL may be reduced as shown in FIG. 15. In contrast, if the diode D is not present, the slew time of the anode voltage V1 of the light-emitting element EL becomes shorter as shown in FIG. 13, and thus the ripple of the cathode voltage may become larger as shown in FIG. 16.

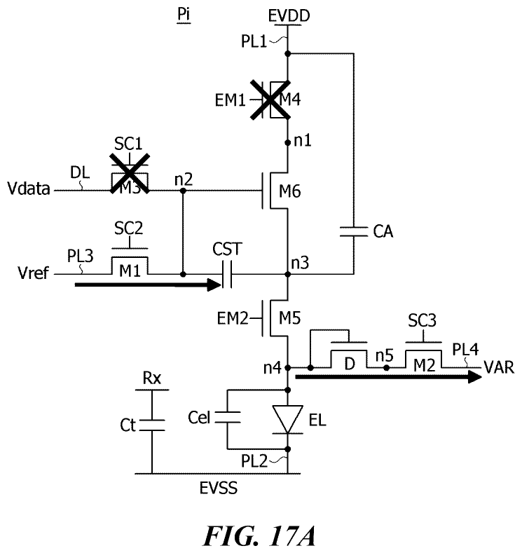

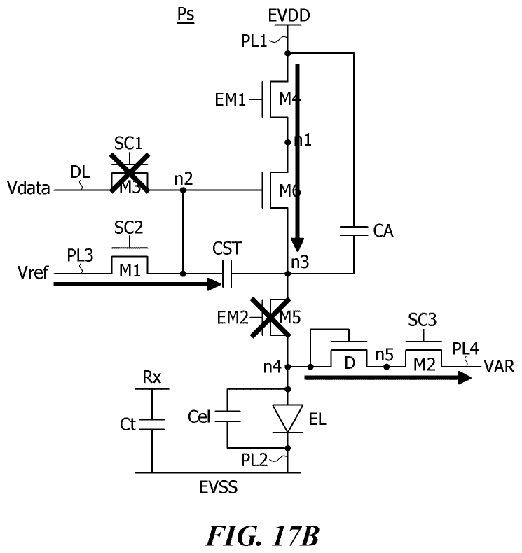

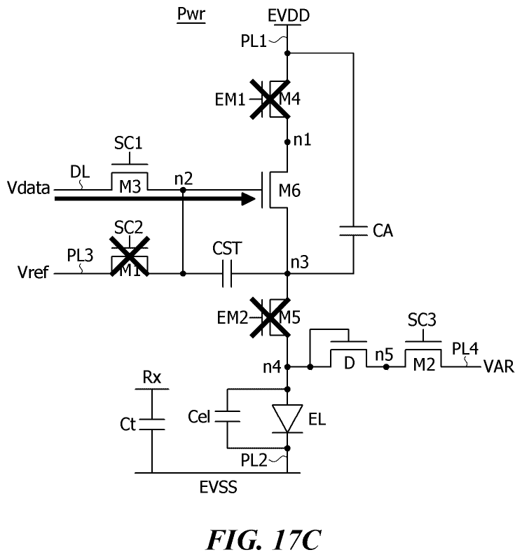

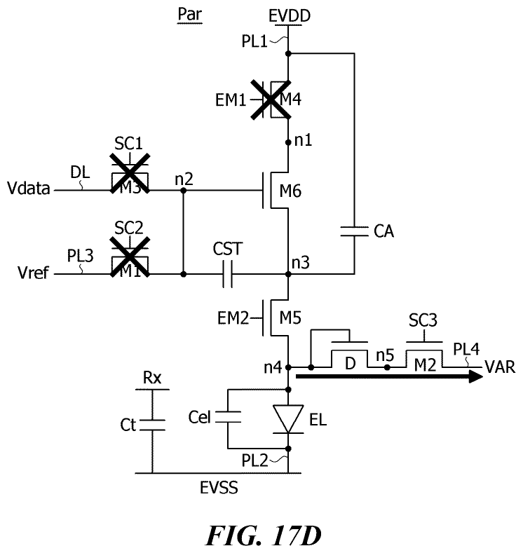

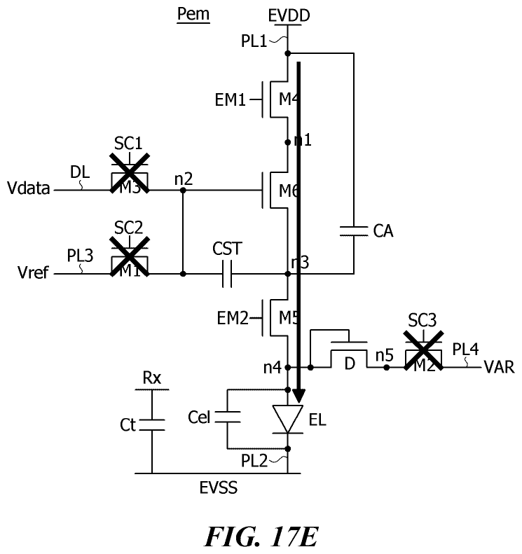

FIGS. 17A to 17E are circuit diagrams illustrating the operation of the pixel circuit shown in FIG. 9, step by step.

Referring to FIG. 10 and FIG. 17A, during the initialization period Pi, the first switch transistor M1, the second switch transistor M2, and the fifth switch transistor M5 are turned on in response to the gate-on voltage VGH of the corresponding gate signals SC2, SC3, and EM2. The diode D is turned on immediately after the second switch transistor M2 is turned on. The third and fourth switch transistors M3 and M4 are turned off in response to the gate-off voltage VGL of the corresponding gate signals SC1 and EM1 during the initialization period Pi. When the initialization period Pi ends, the voltage of the second node n2 is the reference voltage Vref, and the voltages of the third and fourth nodes n3 and n4 are the anode reset voltage VAR.

Referring to FIG. 10 and FIG. 17B, during the sensing period Ps, the first switch transistor M1, the second switch transistor M2, and the diode D are maintained in the on-state, and the fourth switch transistor M4 is turned on in response to the gate-on voltage VGH of the first EM signal EM1. The fifth switch transistor M5 is turned off in response to the gate-off voltage VGL of the second EM signal EM2 during the sensing period Ps. The third switch transistor M3 is in the off-state during the sensing period Ps. During the sensing period Ps, the threshold voltage Vth of the driving transistor M6 is sensed and sampled into the capacitor CST. When the sensing period Ps ends, the voltage of the second node n2 is a reference voltage Vref, and the voltage of the third node n3 is Vref−Vth. When the sensing period Ps ends, the voltage at the fourth node n4 is the anode reset voltage VAR.

Referring to FIG. 10 and FIG. 17C, during the data writing period Pwr, the second switch transistor M2 and the diode D are maintained in the on-state, and the third switch transistor M3 is turned on in response to the gate on voltage VGH of the first scan signal SC1 synchronized with the data voltage Vdata of the pixel data. The first switch transistor M1 and the fourth switch transistor M4 are turned off in response to the gate off voltage VGL of the corresponding gate signals SC2 and EM1 during the data writing period Pwr. The fifth switch transistor M5 is in the off-state during the data writing period Pwr. During the data writing period Pwr, the data voltage Vdata of the pixel data is charged in the capacitors CST and CA. When the data writing period Pwr ends, the voltage of the second node n2 is the data voltage Vdata, and the voltage DTS of the third node n3 is DTS=Vref−Vth+[(Vdata−Vref)*{CST/(CST+CA)}]. When the data writing period Pwr ends, the voltage of the fourth node n4 is the anode reset voltage VAR.

Referring to FIG. 10 and FIG. 17D, during the anode reset period Par, the second switch transistor M2 and the diode D are maintained in the on-state and the fifth switch transistor M5 is turned on in response to the gate-on voltage VGH of the second EM signal EM2. The third switch transistor M3 is turned off in response to the gate-off voltage VGL of the first scan signal SC1 during the anode reset period Par. The first switch transistor M1 and the fourth switch transistor M4 are in the off-state during the anode reset period Par. When the anode reset period Par ends, the voltage DTG of the second node n2 is DTG=Vdata+VAR−Vref+Vth−[(Vdata−Vref)*{CST/(CST+CA)}], and the voltages of the third and fourth nodes n3 and n4 are the anode reset voltage VAR.

Referring to FIG. 10 and FIG. 17E, the fourth and fifth switch transistors M4 and M5 are turned on in response to the gate-on voltage VGH of the corresponding EM signals EM1 and EM2 during the emission period Pem, so that the light-emitting element EL may emit light according to the current Ioled generated in response to the gate-source voltage Vgs of the driving transistor M6. During the emission period Pem, the first switch transistor M1, the second switch transistor M2, and the third switch transistor M3 are turned off in response to the gate-off voltage VGL of the corresponding scan signals SC2, SC3, and SC1. During the emission period Pem, the voltage DTG of the second node n2 is DTG=Vdata+VAR−VRef+Vth−[(Vdata−Vref)*{CST/(CST+CA)}]. During the emission period Pem, the gate-source voltage Vgs of the driving transistor M6 is Vgs=Vdata−Vref+Vth−[(Vdata−Vref)*{CST/(CST+CA)}]. During the emission period Pem, the current Ioled flowing in the light-emitting element EL is Ioled=k(Vgs−Vth)2−k(Vdata−Vref−[(Vdata−Vref)*{CST/(CST+CA)}]) 2=k[(Vdata−Vref)*{CA/(CST+CA)}]2. Here, k is a constant value determined according to the channel ratio and mobility of the driving transistor M6.

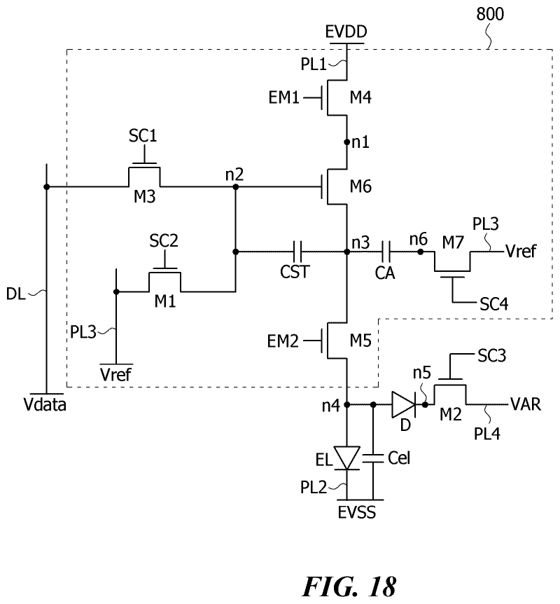

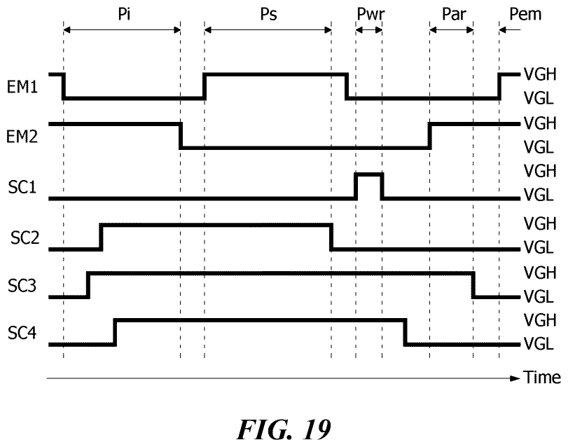

FIG. 18 is a circuit diagram illustrating in detail another example of a compensation circuit in the pixel circuit shown in FIG. 8. FIG. 19 is a waveform diagram illustrating the gate signals shown in FIG. 18. In FIGS. 18 and 19, components that are substantially the same as those in the above-described embodiments are given the same drawing reference numerals, and a detailed description thereof may be omitted.

Referring to FIGS. 18 and 19, the compensation circuit 800 of the pixel circuit may further include a sixth switch transistor M7 that applies a reference voltage Vref to a sixth node n6 in response to a fourth scan signal SC4.

The first capacitor CST is connected between the second node n2 and the third node n3. The second capacitor CA is connected between the third node n3 and the sixth node n6.

The first switch transistor M1 is connected between the third constant voltage node PL3 and the second node n2 and is turned on in response to the gate-on voltage VGH of the second scan signal SC2. When the first switch transistor M1 is turned on in response to the gate-on voltage VGH of the second scan signal SC2 during the initialization period Pi and the sensing period Ps, the reference voltage Vref is applied to the second node n2.

The second switch transistor M2 is connected between the fourth constant voltage node PL4 and the fifth node n5 and is turned on in response to the gate-on voltage VGH of the third scan signal SC3. When the second switch transistor M2 is turned on in response to the gate-on voltage VGH of the third scan signal SC3 during the initialization period Pi, the sensing period Ps, the data writing period Pwr, and the anode reset period Par, the anode reset voltage VAR is applied to the fifth node n5.

The third switch transistor M3 is connected between the data line DL and the second node n2 and is turned on in response to the gate-on voltage VGH of the first scan signal SC1. When the third switch transistor M3 is turned on in response to the gate-on voltage VGH of the first scan signal SC1 during the data writing period Pwr, the data voltage Vdata is applied to the second node n2.

The fourth switch transistor M4 is connected between the first constant voltage node PL1 and the first node n1 and is turned on in response to the gate-on voltage VGH of the first EM signal EM1. When the fourth switch transistor M4 is turned on in response to the gate-on voltage VGH of the first EM signal EM1 during the sensing period Ps and the emission period Pem, the pixel driving voltage EVDD is applied to the first node n1.

The fifth switch transistor M5 is connected between the third node n3 and the fourth node n4 and is turned on in response to the gate-on voltage VGH of the second EM signal EM2. When the fifth switch transistor M5 is turned on in response to the gate-on voltage VGH of the second EM signal EM2 during the initialization period Pi, the anode reset period Par, and the emission period Pem, the third node n3 is electrically connected to the fourth node n4.

The sixth switch transistor M7 is connected between the third constant voltage node PL3 and the sixth node n6 and is turned on in response to the gate-on voltage VGH of the fourth scan signal SC4. The voltage of the fourth scan signal SC4 is generated as a pulse of the gate-on voltage VGH during the initialization period Pi, the sensing period Ps, and the data writing period Pwr, and is a gate-off voltage VGL during other periods Par and Pem. When the sixth switch transistor M7 is turned on in response to the gate-on voltage VGH of the fourth scan signal SC4 during the initialization period Pi, the sensing period Ps, and the data writing period Pwr, a reference voltage is applied to the sixth node n6. The sixth switch transistor M7 includes a first electrode connected to the third constant voltage node PL3, a gate electrode to which a fourth scan signal SC4 is applied, and a second electrode connected to the sixth node n6.

The diode D is connected between the fourth node n4 and the fifth node n5 and is turned on when the voltage of the fourth node n4 is higher than the voltage of the fifth node n5 by a threshold voltage of the diode D. When the diode D is turned on, the fourth node n4 is electrically connected to the fifth node n5. When both the second switch transistor M2 and the diode D are turned on, the anode voltage of the light-emitting element EL may be reset.

During the initialization period Pi, the third scan signal SC3 is inverted from the gate-off voltage VGL to the gate-on voltage VGH, and then the second scan signal SC2 is inverted to the gate-on voltage VGH. Subsequently, the fourth scan signal SC4 is inverted to the gate-on voltage VGH. Accordingly, after the second switch transistor M2 is turned on in the initialization period Pi, the first switch transistor M1 is turned on, and then the sixth switch transistor M7 is turned on.

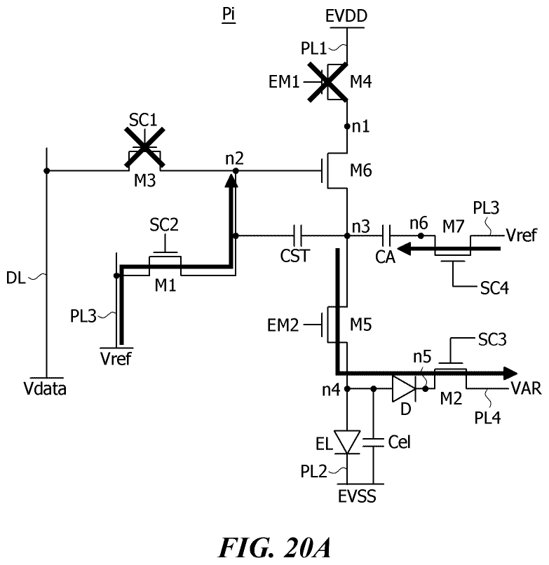

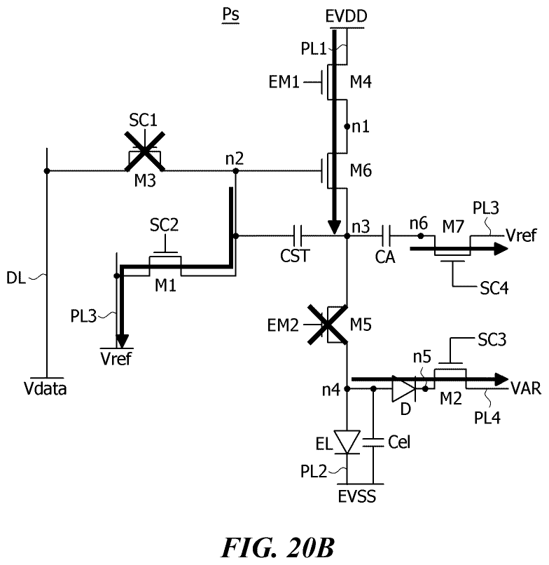

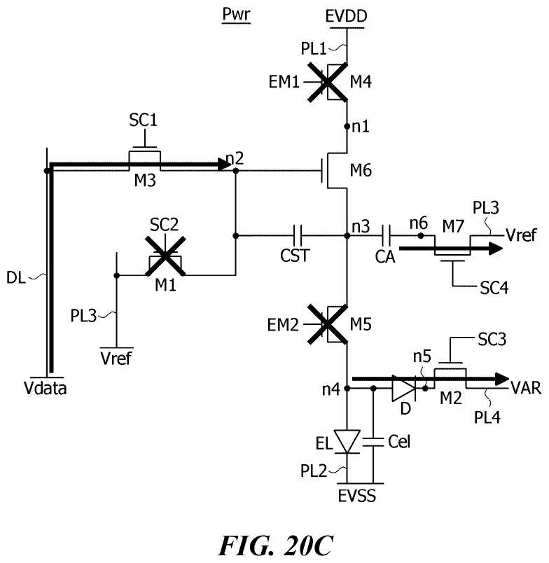

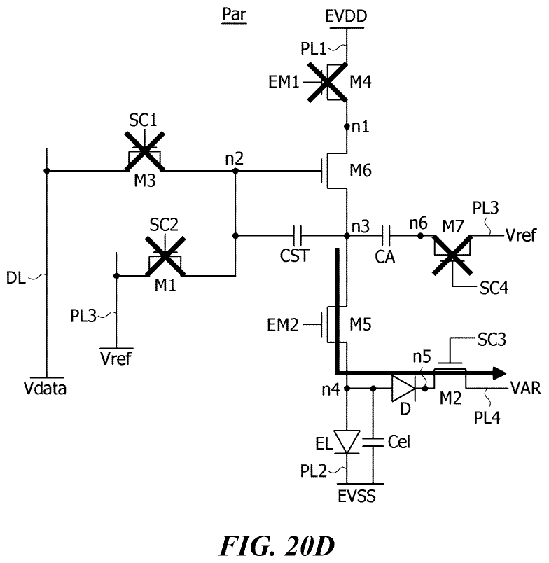

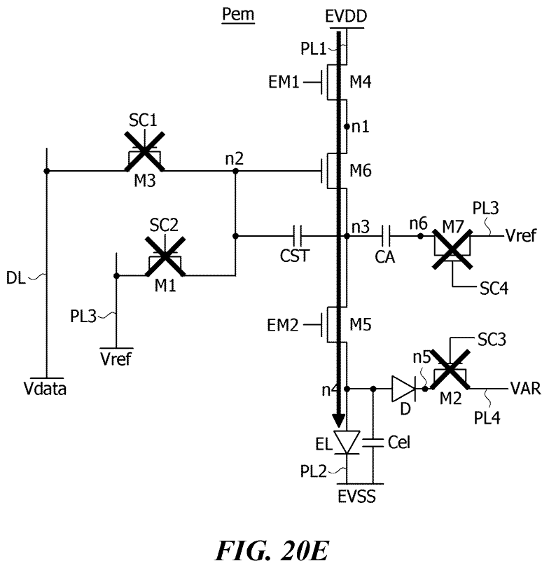

FIGS. 20A to 20E are circuit diagrams illustrating the operation of the pixel circuit shown in FIG. 18, step by step.

Referring to FIGS. 19 and 20A, during the initialization period Pi, the first switch transistor M1, the second switch transistor M2, the fifth switch transistor M5, and the sixth switch transistor M7 are turned on in response to the gate-on voltage VGH of the corresponding gate signals SC2, SC3, EM2, and SC4. The diode D is turned on immediately after the second switch transistor M2 is turned on. The third and fourth switch transistors M3 and M4 are in the off-state during the initialization period Pi. When the initialization period Pi ends, the voltage of the second node n2 is the reference voltage Vref, and the voltages of the third and fourth nodes n3 and n4 are the anode reset voltage VAR. When the initialization period Pi ends, the voltage of the sixth node n6 is the reference voltage Vref.

Referring to FIGS. 19 and 20B, during the sensing period Ps, the first switch transistor M1, the second switch transistor M2, the diode D, and the sixth switch transistor M7 are maintained in the on-state, and the fourth switch transistor M4 is turned on in response to the gate-on voltage VGH of the first EM signal EM1. The fifth switch transistor M5 is turned off in response to the gate-off voltage VGL of the second EM signal EM2 during the sensing period Ps. The third switch transistor M3 is in the off-state during the sensing period Ps. When the sensing period Ps ends, the voltages of the second node n2 and the sixth node n6 are a reference voltage Vref, and the voltage of the third node n3 is Vref−Vth. Here, ‘Vth’ is a threshold voltage of the driving transistor M6. When the sensing period Ps ends, the gate-source voltage of the driving transistor M6 is the threshold voltage Vth.

Referring to FIGS. 19 and 20C, during the data writing period Pwr, the second switch transistor M2, the diode D, and the sixth switch transistor M7 are maintained in the on-state, and the third switch transistor M3 is turned on in response to the gate-on voltage VGH of the first scan signal SC1 synchronized with the data voltage Vdata of the pixel data. The first switch transistor M1 and the fourth switch transistor M4 are turned off in response to the gate-off voltage VGL of the corresponding gate signals SC2 and EM1 during the data writing period Pwr. The fifth switch transistor M5 is in the off-state during the data writing period Pwr. When the data writing period Pwr ends, the voltage of the second node n2 is the data voltage Vdata, and the voltage DTS of the third node n3 is DTS=Vref−Vth+[(Vdata−Vref)*{CST/(CST+CA)}]. When the data writing period Pwr ends, the voltage of the fourth node n4 is the anode reset voltage VAR, and the voltage of the sixth node n6 is the reference voltage Vref.

Referring to FIGS. 19 and 20D, the second switch transistor M2 and the diode D are maintained in the on-state during the anode reset period Par, and the fifth switch transistor M5 is turned on in response to the gate-on voltage VGH of the second EM signal EM2. The third switch transistor M3 and sixth switch transistor M7 are turned off in response to the gate-off voltage VGL of the corresponding scan signals SC1 and SC4 during the anode reset period Par. The first switch transistor M1 and the fourth switch transistor M4 are in the off-state during the anode reset period Par. When the anode reset period Par ends, the voltage DTG of the second node n2 is DTG=Vdata+VAR−Vref+Vth−[(Vdata−Vref)*{CST/(CST+CA)}], and the voltages of the third and fourth nodes n3 and n4 are the anode reset voltage VAR. When the anode reset period Par ends, the voltage of the sixth node n6 is VAR+Vth−[(Vdata−Vref)*{CA/(CST+CA)}].

Referring to FIG. 19 and FIG. 20E, the fourth and fifth switch transistors M4 and M5 are turned on in response to the gate-on voltage VGH of the corresponding EM signals EM1 and EM2 during the emission period Pem, so that the light-emitting element EL may emit light according to the current Ioled generated in response to the gate-source voltage Vgs of the driving transistor M6. During the emission period Pem, the first switch transistor M1, the second switch transistor M2, the third switch transistor M3, and the sixth switch transistor M7 are turned off in response to the gate-off voltage VGL of the corresponding scan signals SC2, SC3, SC1 and SC4. During the emission period Pem, the voltage DTG of the second node n2 is DTG=Vdata+VAR−Vref+Vth−[(Vdata−Vref)*{CST/(CST+CA)}]. During the emission period Pem, the gate-source voltage Vgs of the driving transistor M6 is Vgs=Vdata−Vref+Vth−[(Vdata−Vref)*{CA/(CST+CA)}]. During the emission period Pem, the current Ioled flowing in the light-emitting element EL is Ioled=k(Vgs−Vth)2=k (Vdata−Vref−[(Vdata−Vref)*{CST/(CST+CA)}])2=k[(Vdata−Vref)*{CA/(CST+CA)}]2.

The display device according to an embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, a home appliance, and the like. In addition, the display device according to one or more embodiments of the present disclosure can be applied to an organic light-emitting lighting device or an inorganic light-emitting lighting device.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A pixel circuit comprising:
a light-emitting element;
a compensation circuit configured to supply current to the light-emitting element; and
a diode and a switch transistor connected in series between an anode electrode of the light-emitting element and a first constant voltage node configured to receive an anode reset voltage,
wherein, when the diode and the switch transistor are turned on, the voltage of the anode electrode of the light-emitting element is reset to the anode reset voltage.

2. The pixel circuit according to claim 1, wherein:
the diode includes an anode electrode connected to the anode electrode of the light-emitting element and a cathode electrode connected to the switch transistor, and
the switch transistor is configured to electrically connect the constant voltage node to the cathode electrode of the diode in response to a scan signal.

3. The pixel circuit according to claim 2, wherein a cathode electrode of the light-emitting element is coupled to a touch sensor through a capacitor.

4. The pixel circuit according to claim 1, wherein the compensation circuit includes:
a driving transistor including a first electrode connected to a first node, a gate electrode connected to a second node, and a second electrode connected to a third node;
a first switch transistor connected between a second constant voltage node configured to receive a reference voltage and the second node and configured to be turned on in response to a second scan signal;
a third switch transistor connected between a data line configured to receive a data voltage and the second node and configured to be turned on in response to a first scan signal;
a fourth switch transistor connected between a third constant voltage node configured to receive a pixel driving voltage and the first node and configured to be turned on in response to a first emission signal; and
a fifth switch transistor connected between the third node and a fourth node and configured to be turned on in response to a second emission signal.

5. The pixel circuit according to claim 4, wherein:
the light-emitting element further includes a cathode electrode connected to a fourth constant voltage node configured to receive a pixel ground voltage, and the anode electrode of the light-emitting element is connected to the fourth node,
the switch transistor connected to the diode includes a second switch transistor connected between the first constant voltage node and a fifth node and configured to be turned on in response to a third scan signal, and
the diode includes a transistor including a gate electrode and a first electrode connected to the fourth node, and a second electrode connected to the fifth node.

6. The pixel circuit according to claim 5, wherein:
the reference voltage is lower than the pixel driving voltage and higher than the anode reset voltage, and
the anode reset voltage is higher than the pixel ground voltage.

7. The pixel circuit according to claim 5, wherein the compensation circuit further includes:
a first capacitor connected between the second node and the third node; and
a second capacitor connected between the third constant voltage node and the third node.

8. The pixel circuit according to claim 5, wherein:
the pixel circuit is driven in an order of an initialization period, a sensing period, a data writing period, an anode reset period, and an emission period,
a voltage of the first emission signal is a gate-on voltage during the sensing period and the emission period, and is a gate-off voltage during the initialization period, the data writing period, and the anode reset period,
a voltage of the second emission signal is the gate-on voltage during the initialization period, the anode reset period, and the emission period, and is the gate-off voltage during the sensing period and the data writing period,
a voltage of the first scan signal is the gate-on voltage during the data writing period, and is the gate-off voltage during the initialization period, the sensing period, the anode reset period, and the emission period,
a voltage of the second scan signal is the gate-on voltage during the initialization period and the sensing period, and is the gate-off voltage during the data writing period, the anode reset period, and the emission period,
a voltage of the third scan signal is the gate-on voltage during the initialization period, the sensing period, the data writing period, and the anode reset period, and is the gate-off voltage during the emission period, and
each of the first, second, third, fourth, and fifth switch transistors is configured to be turned on in response to the gate-on voltage and turned off in response to the gate-off voltage.

9. The pixel circuit according to claim 8, wherein the compensation circuit further includes:
a sixth switch transistor connected between the second constant voltage node and a sixth node, and configured to be turned on in response to the gate-on voltage of a fourth scan signal during the initialization period, the sensing period, and the data writing period;
a first capacitor connected between the second node and the third node; and
a second capacitor connected between the third node and the sixth node.

10. A display panel comprising:
a display area in which a plurality of data lines, a plurality of gate lines, a plurality of power lines, and a plurality of sub-pixels are arranged, each of the sub-pixels including a pixel circuit connected to a light-emitting element;
a touch sensor electrically coupled to the light-emitting element; and
a gate driving circuit connected to the gate lines,
wherein the pixel circuit includes:
a light-emitting element;
a compensation circuit configured to supply current to the light-emitting element; and
a diode and a switch transistor connected in series between an anode electrode of the light-emitting element and a first constant voltage node configured to receive an anode reset voltage, and
wherein, when the diode and the switch transistor are turned on, the voltage of the anode electrode of the light-emitting element is reset to the anode reset voltage.

11. The display panel according to claim 10, wherein:
the diode includes an anode electrode connected to the anode electrode of the light-emitting element and a cathode electrode connected to the switch transistor, and
the switch transistor is configured to electrically connect the constant voltage node to the cathode electrode of the diode in response to a scan signal.

12. The display panel according to claim 10, wherein a cathode electrode of the light-emitting element is coupled to a touch sensor through a capacitor.

13. The display panel according to claim 10, wherein:
the compensation circuit includes:
a driving transistor including a first electrode connected to a first node, a gate electrode connected to a second node, and a second electrode connected to a third node;
a first switch transistor connected between a second constant voltage node configured to receive a reference voltage and the second node and configured to be turned on in response to a second scan signal from the gate driving circuit;
a third switch transistor connected between a data line configured to receive a data voltage and the second node and configured to be turned on in response to a first scan signal from the gate driving circuit;
a fourth switch transistor connected between a third constant voltage node configured to receive a pixel driving voltage and the first node and configured to be turned on in response to a first emission signal from the gate driving circuit; and
a fifth switch transistor connected between the third node and a fourth node and configured to be turned on in response to a second emission signal from the gate driving circuit, and
wherein the light-emitting element further includes a cathode electrode connected to a fourth constant voltage node configured to receive a pixel ground voltage, and the anode electrode of the light-emitting element is connected to the fourth node,
the switch transistor connected to the diode includes a second switch transistor connected between the first constant voltage node and a fifth node and configured to be turned on in response to a third scan signal from the gate driving circuit, and
the diode includes a transistor including a gate electrode and a first electrode connected to the fourth node, and a second electrode connected to the fifth node.

14. The display panel according to claim 13, wherein the compensation circuit further includes:
a first capacitor connected between the second node and the third node; and
a second capacitor connected between the third constant voltage node and the third node.

15. The display panel according to claim 13, wherein the compensation circuit further includes:
a sixth switch transistor connected between the second constant voltage node and a sixth node and configured to be turned on in response to a fourth scan signal from the gate driving circuit;
a first capacitor connected between the second node and the third node; and
a second capacitor connected between the third node and the sixth node.

16. A display device comprising:
a display panel including a display area in which a plurality of data lines, a plurality of gate lines, a plurality of power lines, and a plurality of sub-pixels are arranged, each of the sub-pixels including a pixel circuit connected to a light-emitting element; a touch sensor electrically coupled to the light-emitting element; a gate driving circuit connected to the gate lines; and a data driving circuit connected to the data lines,
wherein the pixel circuit includes:
a light-emitting element;
a compensation circuit configured to supply current to the light-emitting element; and
a diode and a switch transistor connected in series between an anode electrode of the light-emitting element and a first constant voltage node configured to receive an anode reset voltage, and
wherein, when the diode and the switch transistor are turned on, the voltage of the anode electrode is reset to the anode reset voltage.

17. The display device according to claim 16, wherein:
the compensation circuit includes:
a driving transistor including a first electrode connected to a first node, a gate electrode connected to a second node, and a second electrode connected to a third node;
a first switch transistor connected between a second constant voltage node configured to receive a reference voltage and the second node and configured to be turned on in response to a second scan signal from the gate driving circuit;
a third switch transistor connected between a data line configured to receive a data voltage from the data driving circuit and the second node and configured to be turned on in response to a first scan signal from the gate driving circuit;
a fourth switch transistor connected between a third constant voltage node configured to receive a pixel driving voltage and the first node and configured to be turned on in response to a first emission signal from the gate driving circuit; and
a fifth switch transistor connected between the third node and a fourth node and configured to be turned on in response to a second emission signal from the gate driving circuit,
the light-emitting element further includes a cathode electrode connected to a fourth constant voltage node configured to receive a pixel ground voltage, and the anode electrode of the light-emitting element is connected to the fourth node,
the switch transistor connected to the diode includes:
a second switch transistor connected between the first constant voltage node and a fifth node and configured to be turned on in response to a third scan signal from the gate driving circuit, and
the diode includes:
a transistor including a gate electrode and a first electrode connected to the fourth node, and a second electrode connected to the fifth node.

18. The display device according to claim 17, wherein:
the pixel circuit is driven in an order of an initialization period, a sensing period, a data writing period, an anode reset period, and an emission period,
a voltage of the first emission signal is a gate-on voltage during the sensing period and the emission period, and is a gate-off voltage during the initialization period, the data writing period, and the anode reset period,
a voltage of the second emission signal is the gate-on voltage during the initialization period, the anode reset period, and the emission period, and is the gate-off voltage during the sensing period and the data writing period,
a voltage of the first scan signal is the gate-on voltage during the data writing period, and is the gate-off voltage during the initialization period, the sensing period, the anode reset period, and the emission period,
a voltage of the second scan signal is the gate-on voltage during the initialization period and the sensing period, and is the gate-off voltage during the data writing period, the anode reset period, and the emission period,
a voltage of the third scan signal is the gate-on voltage during the initialization period, the sensing period, the data writing period, and the anode reset period, and is the gate-off voltage during the emission period, and
each of the first, second, third, fourth, and fifth switch transistors is configured to be turned on in response to the gate-on voltage and turned off in response to the gate-off voltage.

19. The display device according to claim 18, wherein the compensation circuit further includes:
a first capacitor connected between the second node and the third node; and
a second capacitor connected between the third constant voltage node and the third node.

20. The display device according to claim 18, wherein the compensation circuit further includes:
a sixth switch transistor connected between the second constant voltage node and a sixth node and configured to be turned on in response to the gate-on voltage of a fourth scan signal from the gate driving circuit;
a first capacitor connected between the second node and the third node; and
a second capacitor connected between the third node and the sixth node.
